(19) United States
(12) Patent Application Publication
(10) Pub. No.: US 2008/0304821 A1
(43) Pub. Date: Dec. 11, 2008

(54) Camera module package and method of manufacturing the same

(75) Inventors: Won Kyu Jeung, Seoul (KR); Seog Moon Choi, Seoul (KR); Jingli Yuan, Gyeonggi-do (KR); Chang Hyun Lim, Gyeonggi-do (KR); Dae Jun Kim, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/149,751

(22) Filed: May 7, 2008

(30) Foreign Application Priority Data
Jun. 5, 2007 (KR) 10-2007-0055153

(51) Int. Cl. G03B 17/00; H01L 21/00

(52) U.S. Cl. 396/529; 438/66; 257/E21.001

(57) ABSTRACT

The present invention relates to a camera module package having flexibility and a method of manufacturing the same. Provided is the camera module package according to the invention including a silicon wafer mounted with the image sensor in the center of a top surface thereof and provided with pads both sides of the image sensor, a lens unit opened to form a convex lens in a mounting portion of the image sensor in an upper part of the wafer, and a flexible board tightly joined to a bottom surface of the wafer and electrically connected to the pads by an internal pattern. The camera module package can be thinly manufactured and since the camera module package has flexibility, the camera module package can be easily attached to a bendable substrate and to the inside an IT apparatus.

### CROSS-REFERENCE TO RELATED APPLICATIONS

This application claims the benefit of Korean Patent Application No. 10-2007-0055153 filed with the Korea Intellectual Property Office on Jun. 5, 2007, the disclosure of which is incorporated herein by reference.

### BACKGROUND OF THE INVENTION

1. Field of the Invention

The present invention relates to a camera module package having flexibility and a method of manufacturing the same and, more particularly, to a camera module package which has the flexibility and can be thinly manufactured by sequentially stacking a silicon board mounted with an image sensor on a top surface of a flexible board and a lens unit in a wafer level state.

2. Description of the Related Art

In recent years, camera modules are mounted on IT apparatuses including a mobile communication terminal, a PDA (Personal Digital Assistant), and an MP3 player, an automobile, an endoscope, and the like at the time of manufacturing the IT apparatuses, the automobile, the endoscope, and the like, the camera modules are miniaturized and thinned according to a mounting target while conventional camera modules of a 300-thousand pixel class (a VGA (Video Graphic Array) class) are developed to camera modules of higher pixel class with technological development, and the camera modules are changed to implement various additional functions including an automatic focusing function, an optical zooming function, and the like at low fabrication cost.

A currently fabricated camera module is fabricated with an image sensor module fabricated by a wire bonding method (COB: Chip On Board), a flip chip method (COF: Chip On Film), and a chip scale package method mounted on the camera module. The camera module is connected to a main board mainly through an electrical connection member such as a printed circuit board (PCB) or a flexible printed circuit board (FPCB).

However, recently, as the camera module can be mounted directly on the main board in the same manner as a general passive element, the camera module capable of simplifying a manufacturing process and saving fabrication cost is required by a user.

Such camera module is fabricated in a state where an image sensor such as a CCD (Charge-Coupled Device) or a CMOS (Complementary Metal-Oxide Semiconductor) is mainly attached to a board by the COB method or the COF method. An image of an object is focused through the image sensor and is stored in a memory in the inside and outside of the camera module in a data form. The stored data is converted into an electrical signal and is displayed on a display medium such as an LCD (Liquid Crystal Display) or a PC monitor in an apparatus in an image form.

Hereinafter, simplified structures of the camera modules fabricated by the COF method and the COB method which are representative camera module fabricating methods will be described with reference to drawings shown below.

FIG. 1 is an assembly perspective view showing an assembly state of the conventional camera module of the COF method. FIG. 2 is a partial cross-sectional view of the conventional camera module of the COF method.

As shown in the figure, a conventional camera module 1 is configured by sequentially joining a housing 2 an image sensor 3 for converting an image signal inputted through a lens into an electrical signal supported on a bottom surface of the housing, a lens group 4 for focusing an image signal of a subject on the image sensor 3, and a barrel 5 in which the lens group 4 is stocked.

At this time, a mounting flexible printed circuit board (FPCB) 6 attached with chip components of condensers and resistors which are electric components for driving the image sensor 3 composed of a CCD (Charge-Coupled Device) or a CMOS (Complementary Metal-Oxide Semiconductor) is electrically joined to a lower part of the housing 2.

In the conventional camera module 1 configured above, in a state where a plurality of circuit components are mounted on the mounting flexible printed circuit board) 6, an anisotropic conductive film (ACF) 8 is interposed between the board 6 and the image sensor 3 and adhesively fixed to allow electricity to flow on the anisotropic conductive film 8 by applying heat and pressure and an IR filter 7 is attached to a surface opposite to the anisotropic conductive film 8.

In a state where the barrel 5 incorporating the plurality of lens groups 4 is temporarily joined to the housing 2 by screw joining, the previously assembled mounting board 6 is adhesively fixed to a bottom surface of the housing by a separate adhesive as described above.

Meanwhile, after the housing 2 to which the mounting board 6 attached with the image sensor 3 and the barrel 5 are joined are adhesively fixed, the focus adjustment is performed with a subject (a resolution chart) spaced in the front of the barrel 5. In case of the focus adjustment of the camera module 1, the focus adjustment between the lens group 4 and the image sensor 3 is performed according to the control of a vertical transfer distance by the rotation of the barrel 5 screw-joined to the housing 2.

At this time, the focus is adjusted with keeping from the subject at a distance of approximately 50 cm to an infinite distance. The housing 2 and the barrel 5 are adhesively fixed to each other by injecting the adhesive between the housing 2 and the barrel 5 in a state where a focus is adjusted after the final focus adjustment.

However, foreign materials such as particles generated by the friction of a screw-joint portion of the housing 2 and the barrel 5 are dropped onto the top surface of the IR filter 7 or the image sensor 3 and are exposed onto a light receiving region of the image sensor 3 at the time of vertically transferring the barrel 5 by rotating right and left the barrel 5 screw-joined to the housing 2 so as to adjust the focus of an image formed in the image sensor 3 after assembling the barrel 5 mounted with the lens group 4 with the housing 2.

Since an assembly standard of the mounting board 6 and the housing 2 is determined by the IR filter 7 and the IR filter 7 plays an important role in centering the image sensor 3 and the lens group 4 and a large influence is exercised on the foreign materials according to a mounting position of the IR filter 7.

That is, as the mounting position of the IR filter 7 is closer to the image sensor 3, while the foreign materials dropped onto the top surface of the IR filter 7 are easily recognized and as the mounting position of the IR filter 7 is farther from the image sensor 3, the influence on the foreign materials is decreased. Therefore, there is required the design of the camera module to keep a distance between the IR filter 7 and the image sensor 3 to the maximum within the camera module.

Meanwhile, FIGS. 3 and 4 are drawings showing the camera module manufactured in the COB method. FIG. 3 is an exploded perspective view of the camera module manufactured in the conventional COB method. FIG. 4 is a schematic cross-sectional view showing the conventional camera module of the COB method. A conventional camera module 10 is manufactured by joining a printed circuit board 11 mounted with an image sensor 12 of the CCD or the CMOS to a lower part of a housing 13 made of a plastic material and joining a lens barrel 16 having a cylindrical body 15 extending to a lower part of the housing to a tube 14 extending to an upper part of the housing 13.

In the camera module 10, the housing 13 and the lens barrel 16 are joined to each other by the screw-joining of a female screw unit 14a formed in an inner circumference surface of the tube 14 and a male screw unit 15a formed in an outer circumference surface of the cylindrical body 15.

At this time, an IR filter 18 is joined between a lens L mounted on a top surface of the printed circuit board 11, that is, in a bottom part of the lens barrel 16 and the image sensor attached onto a bottom surface of the printed circuit board 11, whereby excessive long-wavelength infrared rays incident into the image sensor 12 is intercepted. In case of the camera module assembled as described above, a final camera module product is manufactured by adhesively fixing the housing 13 and the lens barrel 16 through injecting an adhesive into a gap between the housing 13 and the lens barrel 16 at an optimum focus adjustment spot while rotating the lens barrel 16 bound to the top of the housing 13 by the screw-joining when light incident from a-predetermined object is phase-converted with penetrating the lens L and is focused on a surface of the image sensor 12.

Since this type of camera module is restrictive in height and size thereof, the camera module of the CSP (Chip Scale Package) method shown in FIG. 5 to manufacture an image sensor module having a size approximately equal to a chip without a lead frame for electrically connecting the image sensor has been recently developed in various forms.

Even though the CSP-type package has an advantage that the contamination of the image sensor generated due to the foreign materials can be protected by protecting the image sensor with glass, the CSP-type package has its limit to lowering a height of the CSP-type package since a complete camera module can be configured only in case that the lens and the lens barrel supporting the lens are mounted on an upper part of the CSP-type package.

Accordingly, the camera module manufactured in the above-mentioned method has a limit in decrement in a size and decrement in a thickness and has the low flexibility of a shape change since all the camera modules are configured in a rigid material and a rigid form. There is raised a problem that the conventional camera module may be impossible to be mounted on a flexible substrate and an IT apparatus deformable in various forms by using the flexible substrate which are developable in the future.

### SUMMARY OF THE INVENTION

Accordingly, the present invention has been made to solve the foregoing disadvantages and problems raised in a conventional camera module and a method of manufacturing the same and therefore an advantage of the present invention is to provide a camera module package which has the flexibility and can be thinly manufactured by manufacturing a flexible board, a silicon board mounted with an image sensor and a film-like lens unit opened in an upper part of the image sensor in a wafer level state. Another advantage of the present invention is to provide a camera module package capable of preventing foreign materials generated at the time of manufacturing a camera module from being inputted by manufacturing and dicing the camera module itself in an array form in the wafer level state.

The advantages of the present invention are achieved by providing a camera module package including a silicon wafer mounted with the image sensor in a center of a top surface thereof and provided with pads both sides of the image sensor, a lens unit opened to form a convex lens in a mounting portion of the image sensor in an upper part of the wafer, and a flexible board tightly joined to a bottom surface of the wafer and electrically connected to the pads by an internal pattern.

An IR filter layer for selectively shielding ultraviolet rays included in incident light is further formed on a top surface of the lens formed in the center of the lens unit.

A metallic thin layer for preventing external scattered light from penetrating is formed in the outside of the lens.

It is preferable that the wafer is made of a general silicon material and has flexibility by being thinned as possible.

At this time, the wafer is formed in a thickness of approximately 50 μm after the thinning process.

The pad are electrically conducted by forming a via-hole is formed in a formation part of the pad after mounting the image sensor and forming the pad on the wafer, and injecting a conductive material into the via-hole by a plating method using electrolytic copper plating and a method of printing and curing conductive paste.

The lens unit is formed by a laminating method or a spin coating method using a liquid material or a film, and more specifically, the lens unit may be formed by monolayer or multilayer polymer laminating method using a material of the same kind or different materials, a polymer laminating method using a film sheet having the pattern, and a spin-coating method using the material of the same kind or the different materials.

A flexible substrate provided with the pad and a circuit pattern forming a conductive line therein by being in contact with a via electrically conducted to the pad is tightly joined to a bottom of the silicon wafer.

At this time, the substrate is made of a high molecular material such as polyimide.

Accordingly, the camera module having the above-mentioned configuration can be thinly manufactured by sequentially the flexible substrate, the wafer formed in a thin thickness, and the lens unit plated on the wafer in a thin film shape. The camera module which is bendable as a whole and is flexible can be manufactured by forming the flexible substrate, and the wafer and the lens unit laminated on the flexible substrate in the thin film shape having a predetermined thickness.

Meanwhile, another advantage of the present invention is achieved by providing the method of manufacturing the camera module package including the steps of: mounting an image sensor and pads on a top surface of a wafer with equal spacing; attaching a support body for protecting the image sensor and the pads onto the wafer, and supporting the wafer; thinning one surface of the wafer so as to make the wafer thin; etching the wafer to form a via-hole on a surface opposite to a mounting surface of the pad; forming a conductive line by injecting conductive paste into the via-hole formed in the wafer; adhesively fixing a flexible substrate in which an internal circuit pattern is formed on a conductive line formation surface of the wafer; removing the support body attached to an upper part of the image sensor; forming a lens unit on top surfaces of the image sensor and the pad of the wafer by laminating or spin-coating; and dividing the completed camera module package into individual camera module packages by dicing the completed package in a wafer level state.

The method of manufacturing the camera module package further includes the steps of forming an IR filter layer on the top surface of the lens formed in the lens unit in a convex shape and forming a metallic thin layer for preventing scattered light from penetrating on a top surface of the lens unit before the step of dividing the camera module package into the individual camera module packages by dicing the camera module package.

At this time, the wafer is formed in a thickness of approximately 50 μm by thinning a surface opposite to the mounting surface of the image sensor and the pads in the step of thinning the wafer, whereby the wafer has flexibility like a comparatively thin paper.

The via-hole is formed by dry etching. The general dry etching is performed by a DRIE (Dry Reactive Ion Etching) method to form a resist layer by performing a photolithography process and open only a part of the resist layer to be etched.

A wall surface of the via-hole formed at the time of etching the wafer may be formed at a right angle or of a taper surface having a predetermined angle.

The step of forming the conductive line by injecting conductive paste into the via-hole includes a paste injecting method for curing the paste through a reflow device after printing the conductive paste or solder paste on the wafer and a plating method for form a wire by copper-plating a seed layer after forming the seed layer to planarize the copper-plated surface through a CMP (Chemical Mechanical Planarization) process.

Meanwhile, the lens unit is formed mainly by a polymer laminating method and a spin-coating method. In addition, the lens unit may be manufactured by a method of laminating at least two layers, a method using patterned layers, a method using a mask, a direct forming method using an ion beam, and a replica method using a mold in the step of forming the lens unit on the top surface of the wafer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an assembly perspective view showing an assembly state of a conventional COF-type camera module;

FIG. 2 is a partial cross-sectional view of the conventional COF-type camera module;

FIG. 3 is an exploded perspective view of the conventional camera module manufactured in the COB type;

FIG. 4 is a schematic cross-sectional view of the conventional COB-type camera module;

FIG. 5 is a cross-sectional view of a conventional CSP-type image sensor module;

FIG. 6 is a cross-sectional view of a camera module package according to the invention;

FIG. 7 is a cross-sectional view of a camera module package according to the invention in which a metallic thin layer is formed;

FIG. 8 is a cross-sectional view of a camera module package according to the invention which is provided with an IR filter layer;

FIGS. 9 to 17 are flowcharts for a method of manufacturing the camera module package according to the invention;

FIGS. 18A to 18E are flowcharts in which a lens unit is formed by a laminating method using a monolayer film sheet adopted in the invention;

FIGS. 19A to 19F are flowcharts in which the lens unit is formed by the laminating method using a multilayer film sheet adopted in the invention;

FIGS. 20A to 20E are flowcharts in which the lens unit is formed by the laminating method using a film sheet having a pattern adopted in the invention; and

FIGS. 21A to 21E are flowcharts in which the lens unit is formed by a spin coating method using a liquid polymer adopted in the invention.

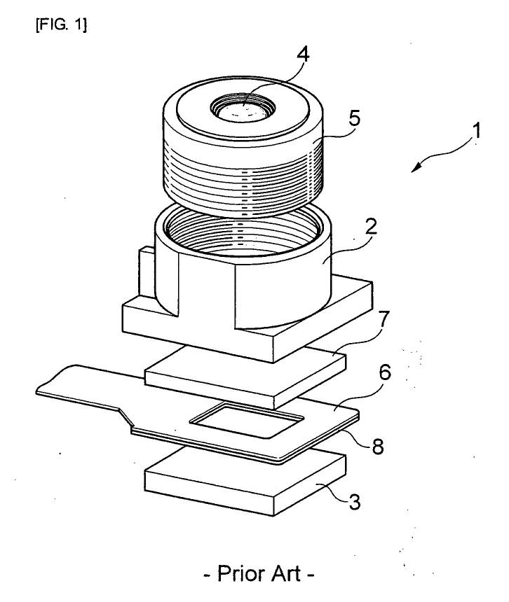

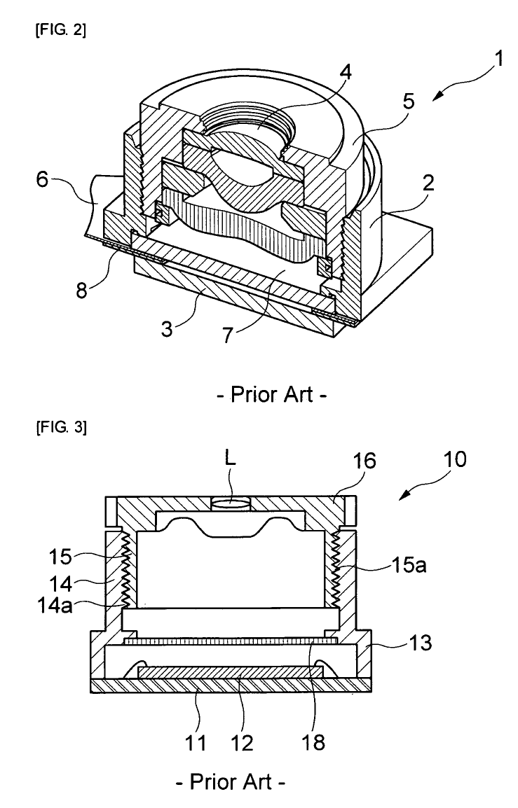

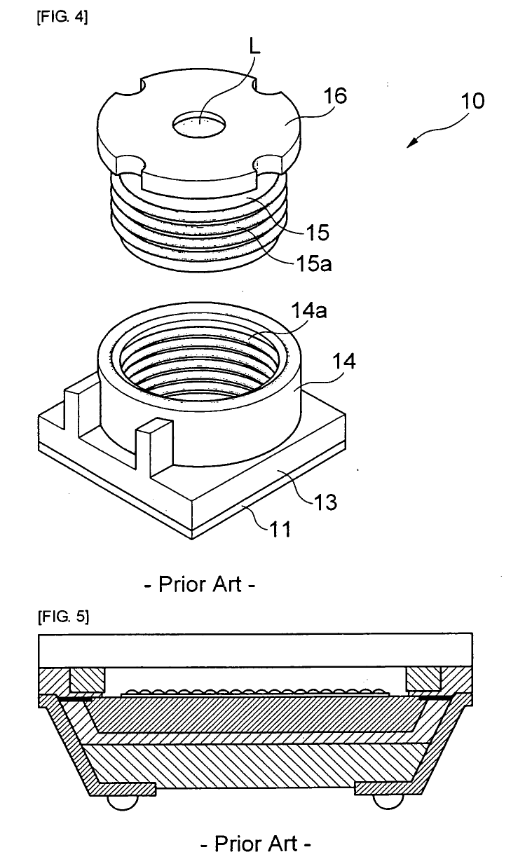

### DETAILED DESCRIPTION OF THE PREFERRED EMBODIMENTS

### Structure of Camera Module

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

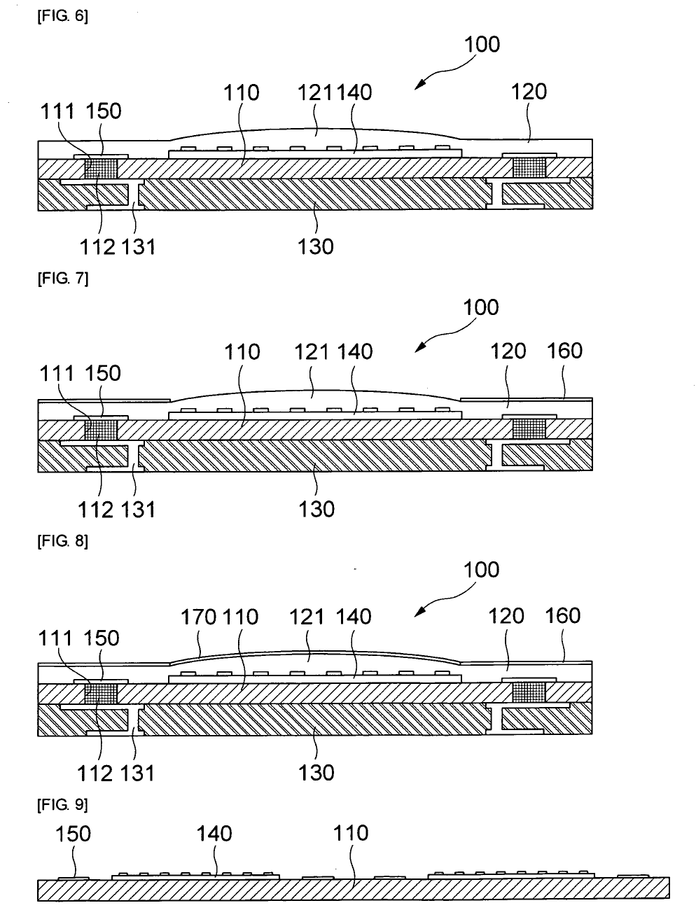

First, FIG. 6 is a cross-sectional view of a camera module package according to the invention, FIG. 7 is a cross-sectional view of a camera module package according to the invention in which a metallic thin layer is formed, and FIG. 8 is a cross-sectional view of a camera module package according to the invention which is provided with an IR filter layer.

As shown in the figure, a camera module 100 according to the invention includes a wafer 110 arranged in a wafer level state, a lens unit 120 opened on a top surface of the wafer 110, and a flexible board 130 tightly joined onto a bottom surface of the wafer 110.

The wafer 110 includes a silicon wafer 110 made of silicon. An image sensor (a microlens) 140 is mounted on a top surface of the wafer 110 and a plurality of pads 150 are mounted in the outside of the wafer 110. The wafer 110 is thinned as possible and therefore becomes flexible, whereby the wafer 110 is formed in a thickness of approximately 50 μm and has flexibility.

At this time, the pads 150 formed on the top surface of the wafer 110 may be constituted of any one of a pad having a general size or an extension pad.

A via-hole 111 is formed in a position on the wafer 110 in which the pad 150 is formed and conductive paste 112 is charged in the inside of the via-hole 111. The conductive paste 112 charged in the inside of the via-hole 111 is charged in a plating method using electrolytic copper plating and a method of curing the conductive paste 112 through printing the conductive paste 112. The conductive paste 112 forms an electric conductive line with being in contact with a bottom surface of the pad 150.

Meanwhile, the lens unit 120 is opened onto a front surface of the wafer 110 so as to open an image sensor 140 mounted on the top surface of the wafer 110 and the pad 150. At this time, in the lens unit 120, the top of a part mounted with the image sensor 140 is constituted of a convex lens 121.

The lens unit 120 is formed in the top of the wafer 110 by coating the top of the wafer 110 with a liquid material, or by laminating or spin coating using a film.

Moreover, a monolayer polymer laminating method, a multilayer laminating method using different materials or a spin coating method, a method using a grayscale mask, and a replica method using a mold can be applied to the lens unit 120 and a detailed method of forming the lens unit 120 will be described below.

Light reflected on a subject (not shown) including external light is incident into the lens unit 120 through a lens 121 formed in the center of the lens unit in a convex shape. The light incident through the lens 121 is received in the image sensor 140 and is converted into an image signal, and the image signal is displayed using an image by the combination of the image signal in the image sensor 140.

At this time, the lens 121 has a focus distance to focus on a light receiving unit of the image sensor 140. In this case, the lens unit 120 including the lens 121 can preferably adjust the number of the lenses 121 and the height of the lens 121 by the multilayer laminating method using the different materials.

Herein, in the lens unit 120, the external light is preferably incident into the image sensor 140 through the lens 121 formed in the center of the lens unit 120 and therefore a metallic thin layer 160 is formed so as to intercept the external light from being incident into while allowing the light to be incident into the outline of the lens 121 formed in the convex shape only through the lens 121.

The metallic thin layer 160 is preferably formed of a black colored thin film to intercept the transmission of the light.

Since the light incident through the lens 121 includes infrared rays, an IR filter layer 170 for shielding the infrared rays included in the incident light is formed on the top surface of the lens 121.

The IR filter layer 170 may be formed by depositing, coating, and applying multiple thin-films and the IR filter layer 170 may be formed on the top surface of the image sensor 140 mounted on the top surface of the wafer 110 before the formation of the lens unit 121 as the case may be.

Meanwhile, a flexible substrate 130 is tightly joined onto the bottom surface of the wafer 110.

The flexible substrate 130 is mainly made of a high molecular material such as polyimide (PI) and a circuit pattern 131 is formed in the flexible substrate 130.

Therefore, the substrate 130 tightly joined onto the bottom surface of the wafer 110 is electrically connected to the pad 150 with the circuit pattern 131 formed in the substrate 130 being in contact with the conductive paste 112 charged in the via-hole 111 formed on the wafer 110.

A method of manufacturing the camera module according to the invention with the above-mentioned configuration will be described below in more detail with reference to FIGS. 9 to 17.

### Method of Manufacturing Camera Module Package

FIGS. 9 to 17 are flowcharts illustrating a method of manufacturing the camera module package according to the invention. As shown in the figures, the camera module package 100 includes the steps of tightly joining the flexible substrate 130 onto the bottom surface of the wafer 110 mounted with the image sensor 140 and the pad 150 and forming the lens unit 120 which includes the image sensor 140 and the pad, and is opened onto the front surface of the wafer 110 on the top surface of the wafer 110.

More specifically, the image sensor 140 and the pad 150 are mounted on the top surface of the wafer 110 of a wafer level state, which is made of the silicon as shown in FIG. 9.

After then, the wafer 110 is formed in a comparatively thin thickness by thinning a surface opposite to a mounting surface of the image sensor 140 and the pad 150 (see FIG. 11).

At this time, the wafer 110 is formed in a thickness of approximately 50 μm by a thinning process and therefore becomes flexible.

A reason of thinning the wafer 110 is to slim the camera module according to the invention and to manufacture a camera module bendable by applying external force to the camera module as a whole or a self-bendable camera module at the time of manufacturing a camera module manufactured through a process performed hereafter.

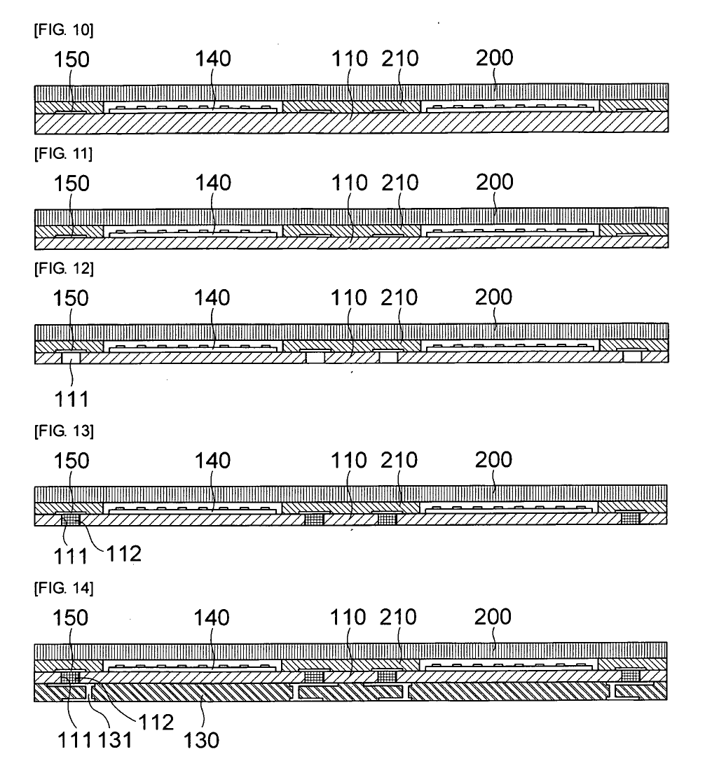

Herein, the method of manufacturing the camera module includes a step of forming, in the top of the wafer 110, a support body 200 including a support unit 210 for protecting the image sensor 140 and the pad 150 which are mounted on the top surface of the wafer 110 and supporting the wafer 110 thinned after the tinning process in a plane state before the step of thinning the wafer 110 (see FIG. 10). The top surface of the image sensor 140 is protected by a cavity formed between the support body 200 and the top surface of the wafer 110.

After then, the thinning of the wafer 110 and a substrate adhering process thereafter are performed in a state that the support body 200 is attached to the top of the wafer 110.

Next, the via-hole 111 is formed on a surface opposite to the wafer 110 on which the pad 150 is formed by etching as shown in FIG. 12.

The via-hole 111 may be formed by wet etching, but the via-hole 111 is formed by dry etching such as DRIE (Dry Reactive Ion Etching) by opening only a part of a resist layer to be etched in case that the resist layer is formed in the step of thinning the wafer 110.

Moreover, the etching characteristic of the wafer 110 is determined according to the material of the wafer and the type, concentration, and temperature of etchant. An etching speed can be controlled fast or slow according to the type, concentration, and temperature of the etchant.

At this time, a wall surface of the via-hole 111 may be formed at a right angle or of a taper surface having a predetermined angle.

In case that the side of the via-hole 111 is formed at a right angle, the pad and a good conductive line are difficult to be formed at the time of injecting the conductive paste into the via-hole of the wafer, whereby the side of the via-hole is preferably formed of a tapered slope.

However, in case that a method of plating metal without injecting the conductive paste through the via-hole of the wafer, the good conductive line is formed by uniform charging even though the side of the via-hole is formed at the right angle, it is preferable that the side of the via-hole is not limited to being formed of the slope.

Next, the conductive line is formed by injecting the conductive paste 112 into the via-hole 111 formed on the wafer 110 (see FIG. 13).

At this time, the method of injecting the conductive paste 112 into the via-hole 111 is performed by a method of printing the conductive paste containing solder paste and the method of plating the metal.

The method of printing the conductive paste 112 is a method of curing the paste injected into the via-hole 111 through a reflow device or an oven after printing the conductive paste 112 to inject the conductive paste 112 into the via-hole 111 formed on the wafer 110 and the method of plating the metal is a method of forming the pad 150 and a desired wire by leaving only the metal charged in the via-hole 111 when CMP (Chemical Mechanical Planarization) is performed by performing the electrolytic copper plating after plating seed metal.

As described above, the flexible substrate 130 is adhesively fixed (see FIG. 14) after the curing by injecting the conductive paste 112 into the via-hole 111 etched on the wafer 110 is completed and the pad 150 and the conductive paste 112 in which the conductive line is formed are formed coplanarily with the wafer 110.

The flexible substrate 130 is provided with the circuit pattern 131 electrically connected thereto with being in contact with the conductive paste 112 charged in the via-hole 111 in the inside of a position corresponding to the formation portion of the via-hole 111 of the wafer 110.

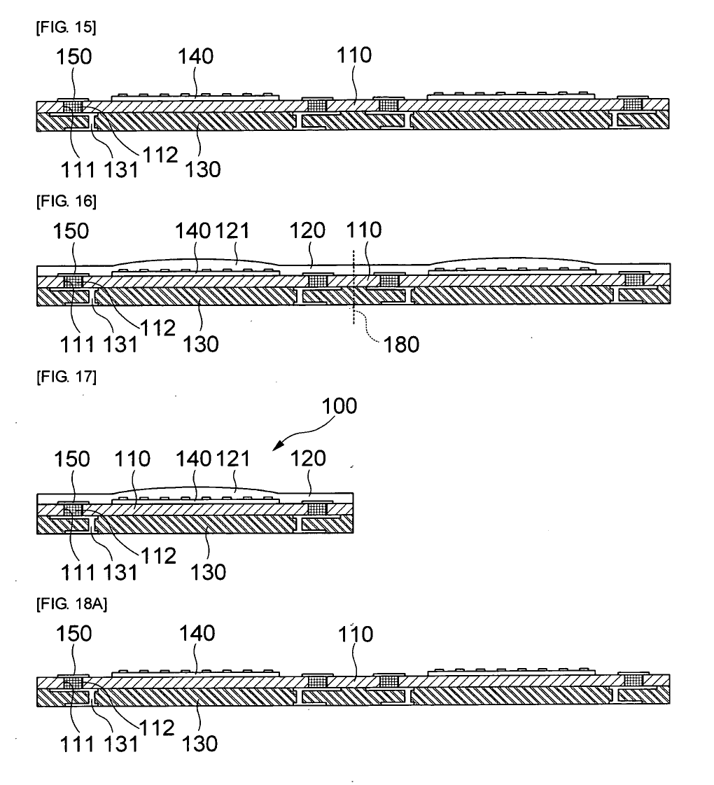

Next, after removing the support body 120 including the support unit 121 attached to the top surface of the wafer 110 (see FIG. 15), the thin-film lens unit 120 is formed in the image sensor 140 on the wafer 110 and the top of the mounting surface of the pad 150 (see FIG. 16).

The lens unit 120 is composed of the lens 121 having a convex center portion. The lens unit 120 is formed on the top surface of the wafer 110 by the laminating method using a film made of a polymer material and the spin coating method using the liquid polymer.

The above-mentioned method of forming the lens unit 120 will be described below in more detail.

Last, the wafer 110 is divided into individual packages and manufacturing the camera module is completed (see FIG. 17) by dicing the wafer 110 provided with the lens unit 120 formed the top surface of the wafer 110 in the wafer level state along a scribe line 180 formed between adjacent pads 150 (see FIG. 16).

As described above, the method of manufacturing the camera module manufactured in a package form according to the invention further includes the steps of forming the IR filter layer 170 on the top surface the lens 121 formed in the lens unit 120 before dicing the wafer 110 into the individual packages and forming the metallic thin layer 160 for preventing scattered light from penetrating on the top surface of the lens unit 120 other than the lens 121.

Meanwhile, the above-mentioned method of forming the lens unit 120 on the top surface of the wafer 110 can be performed through representative embodiments described below and the detailed method of forming the lens will be described as follows.

The lens unit 120 may be formed by the laminating method using a film sheet and the spin coating method using the liquid material.

### First Embodiment

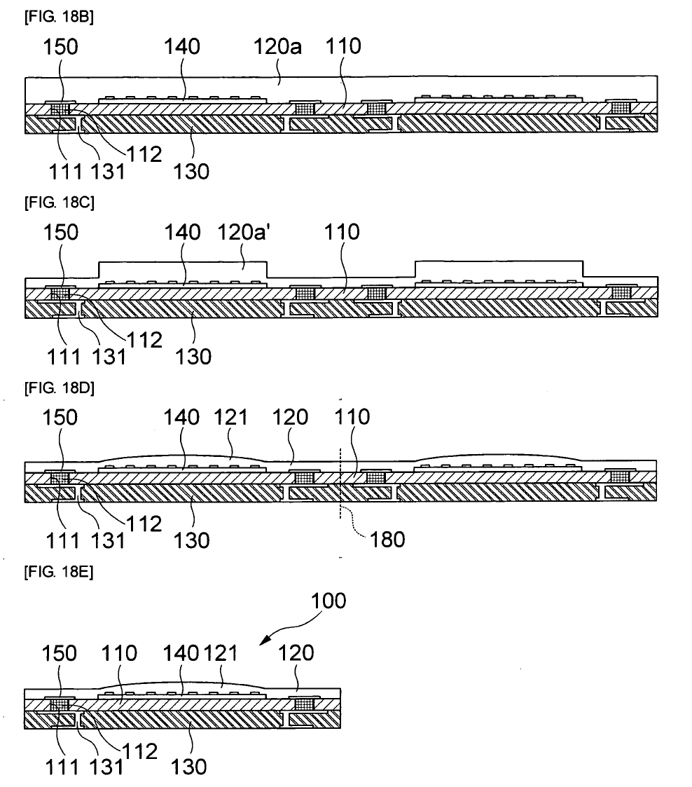

FIGS. 18A to 18E are flowcharts in which a lens unit is formed by the laminating method using the monolayer film sheet adopted in the invention. As shown in the figure, a film sheet 120a made of a polymer used at the time of manufacturing the lens is adhered onto the top surface of the wafer 110 including the top surface of the image sensor 140 by using a laminator apparatus (see FIG. 18B).

At this time, the film sheet 120a is preferably made of a photosensitive material.

Next, a pattern 120a′ is formed on the film sheet 120a by a photolithography process, that is, processes such as an exposure, a development, and the like (see FIG. 18C) and the lens 121 is formed as a formation part of the pattern 120a is softened by performing a reflow process in a state that the pattern 120a′ is formed on the film sheet 120a (see FIG. 18D).

After then, the individual camera module packages are manufactured as the wafer 110 is diced along the scribe line 180 formed between the adjacent pads (150) on the top surface of the wafer 110 (see FIG. 18D).

### Second Embodiment

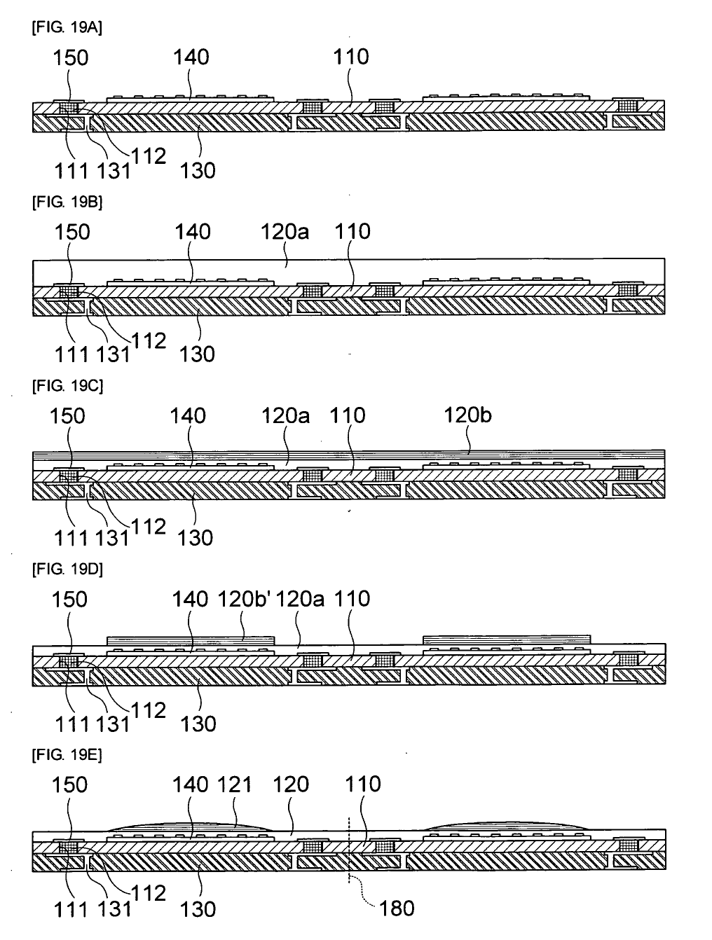

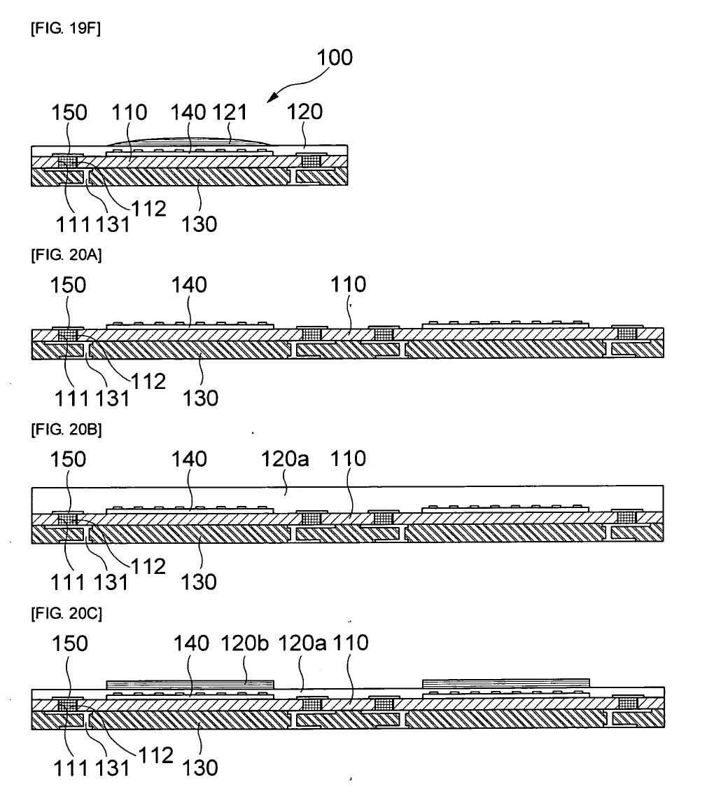

FIGS. 19A to 19F are flowcharts in which the lens unit is formed by the laminating method using the multilayer film sheet adopted in the invention. As shown in the figure, a first film sheet 120a is adhered onto the top surface of the wafer 110 including the top surface of the image sensor 140 by using the laminator apparatus (see FIG. 19B).

The top surface of the first film sheet 120a is thinned by the exposure, the development, or the thinning process. A second film sheet 120b is laminated on the top surface of the first film sheet 120a (see FIG. 19C).

The second film sheet 120b is made of a photosensitive material and a pattern 120b′ is formed on the second film sheet 120b through the photolithography process, that the processes such as the exposure, the development, and the like (see FIG. 19D).

Herein, a principal object to adhere the first film sheet 120a first is to strength adhesion force between the second film sheet 120b to be applied hereafter and the top surface of the image sensor 140.

Another object is to easily perform the focus adjustment by adjusting a distance between the second film sheet 120b formed on the top surface of the first film sheet 120a and the image sensor 140 through adjusting a thickness of the first film sheet 120a.

Next, the lens 121 is formed as a formation part of the pattern 120b′ is softened by performing the reflow process in a state that the pattern 120b′ is formed on the second film sheet 120b (see FIG. 19E).

After then, the individual camera module packages are manufactured as the wafer 110 is diced along the scribe line 180 formed between the adjacent pads (150) on the top surface of the wafer 110 (see FIG. 19F).

### Third Embodiment

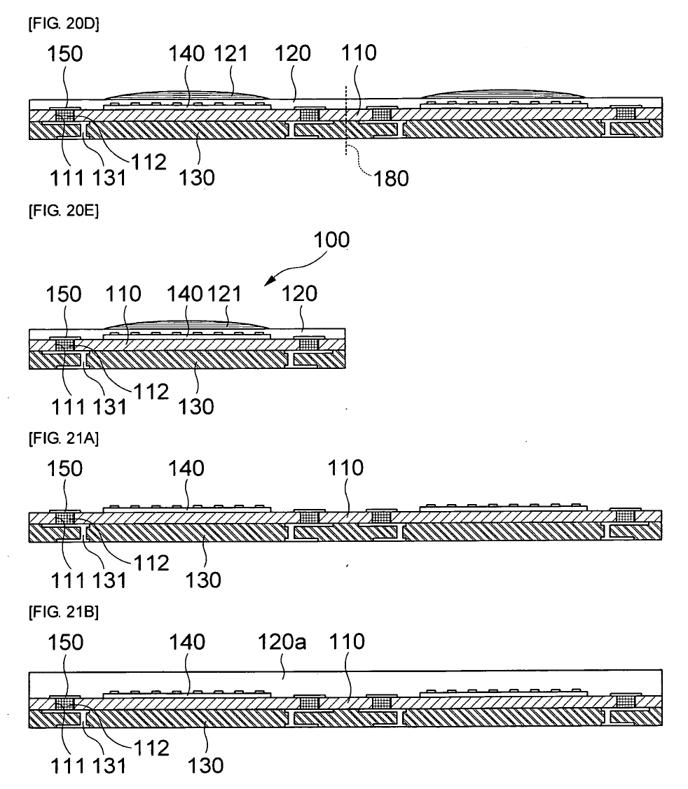

FIGS. 20A to 20E are flowcharts in which the lens unit is formed by the laminating method using the film sheet having the pattern adopted in the invention. As shown in the figure, the first film sheet 120a is adhered onto the top surface of the wafer 110 including the top surface of the image sensor 140 by using the laminator apparatus (see FIG. 20B).

The top surface of the first film sheet 120a is thinned by the exposure, the development, or the thinning process. The second film sheet 120b having patterns arranged with equal spacing is laminated on the top surface of the first film sheet 120a (see FIG. 20C).

Since the lens 121 may be formed without the process such as the exposure or the development, the second film sheet 120b needs not to be made of the photosensitive material. The photolithography process for forming the lens pattern 121b′ described in the above-mentioned embodiments may be omitted.

Herein, the principal object to adhere the first film sheet 120a first is to strength the adhesion force between the second film sheet 120b to be applied hereafter and the top surface of the image sensor 140.

Another object is to easily perform the focus adjustment by adjusting the distance between the second film sheet 120b formed on the top surface of the first film sheet 120a and the image sensor 140 through adjusting the thickness of the first film sheet 120a.

Next, the lens 121 is formed as a formation part of the pattern 120b′ is softened by performing the reflow process in a state that the pattern 120b′ is formed on the second film sheet 120b (see FIG. 20D).

After then, the individual camera module packages are manufactured as the wafer 110 is diced along the scribe line 180 formed between the adjacent pads 150 on the top surface of the wafer 110 (see FIG. 20E).

### Fourth Embodiment

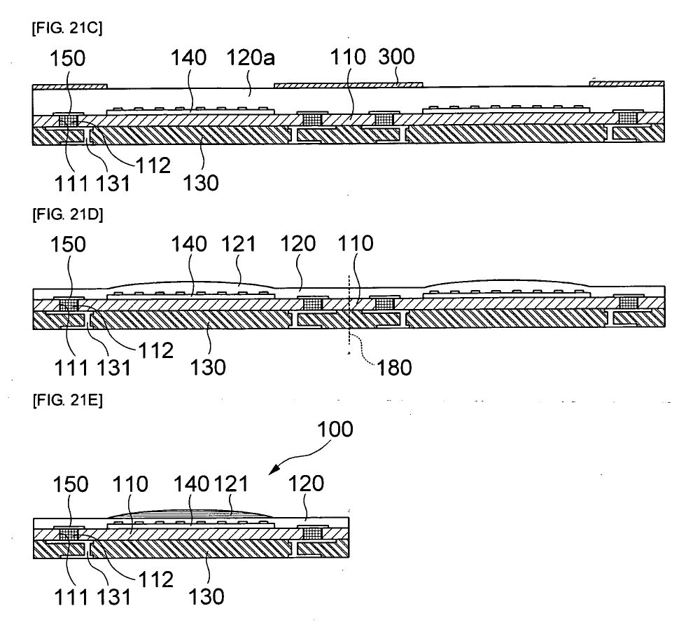

FIGS. 21A to 21E are flowcharts in which the lens unit is formed by the spin coating method using the liquid polymer adopted in the invention. As shown in the figure, the liquid polymer 120a used at the time of the manufacturing the lens is spin-coated on the top surface of the wafer 110 including the top surface of the image sensor 140 (see FIG. 21B).

Next, the pattern is formed by curing the wafer 110 having the spin-coated layer 120a formed on the top surface of the wafer 110 and performing the lithography process on the cured spin-coated layer 120a having a mask 300 formed thereon (see FIG. 12c).

Next, the lens 121 is formed as a formation part of the pattern 120b′ is softened by performing the reflow process in a state that the pattern using the mask 300 is formed on the spin-coated layer 120a (see FIG. 21D).

After then, the individual camera module packages are manufactured as the wafer 110 is diced along the scribe line 180 formed between the adjacent pads 150 on the top surface of the wafer 110 (see FIG. 20E).

As described above, since the camera module package according to the invention can be thinly manufactured by laminating a flexible board, a silicon board mounted with an image sensor and a film-like lens unit opened in an upper part of the image sensor in a wafer level state, and since the camera module package according to the invention has the flexibility, the camera module package can be easily attached to a bendable substrate and to the inside of an IT apparatus.

The camera module package according to the invention has high design flexibility and the camera module package according to the invention can be mounted irrespective of a mounting target by camera module package's own flexibility.

Since the lens and module can has the flexibility like human eyes, the camera module package according to the invention can reduce the distortion of a screen displayed by an output unit.

While preferred embodiments of the present invention have been shown and described for exemplification, it will be apparent to those skilled in the art that modifications and variations can be made without departing from the spirit and scope of the invention as defined by the appended claims.

1. A camera module package comprising:
a wafer mounted with an image sensor in a center of a top surface thereof and provided with pads both sides of the image sensor;
a lens unit opened in an upper part of the wafer and provided with a lens in a mounting portion of the image sensor; and
a flexible board tightly joined to a bottom surface of the wafer and electrically connected to the pads by an internal pattern.

2. The camera module package according to claim 1, wherein an IR filter layer is formed on a top surface of the lens in the center of the lens unit.

3. The camera module package according to claim 1, wherein the IR filter layer is formed on a top surface of the image sensor mounted on the top surface of the wafer.

4. The camera module package according to claim 1, wherein a metallic thin layer for preventing external scattered light from penetrating is formed on the top surface of the lens unit in the outside of the lens.

5. The camera module package according to claim 4, wherein the metallic thin layer is formed of a black colored thin film to intercept the transmission of light.

6. The camera module package according to claim 1, wherein the wafer has flexibility by being made of a silicon material and is thinned in a thickness of approximately 50 μm.

7. The camera module package according to claim 1, wherein a via-hole is formed on a surface of the wafer opposite to a pad formation surface.

8. The camera module package according to claim 7, wherein a side wall of the via-hole is formed at a right angle or of a taper surface.

9. The camera module package according to claim 7, wherein a conductive line is formed by injecting conductive paste into the via-hole.

10. The camera module package according to claim 1, wherein the lens unit is formed by laminating or spin-coating a liquid material or a film sheet.

11. The camera module package according to claim 10, wherein the liquid material or the film sheet is made of a polymer material.

12. The camera module package according to claim 1, wherein the substrate is made of a high-molecular material such as polyimide.

13. A method of manufacturing a camera module package comprising:
mounting an image sensor and pads dn a top surface of a wafer with equal spacing;
thinning one surface of the wafer so as to make the wafer thin;
etching the wafer to form a via-hole on a surface opposite to a mounting surface of the pad;
forming a conductive line by injecting conductive paste into the via-hole formed in the wafer;
adhesively fixing a flexible substrate in which an internal circuit pattern is formed on a conductive line formation surface of the wafer;
forming a lens unit on top surfaces of the image sensor and the pad of the wafer by laminating or spin-coating; and
dividing the completed camera module package into individual camera module packages by dicing the completed package in a wafer level state.

14. The method of manufacturing the camera module package according to claim 13 further includes attaching a support body onto the wafer so as to protect the image sensor and the pads and support the wafer before thinning the wafer.

15. The method of manufacturing the camera module package according to claim 13 further includes removing the support body attached onto the top surface of the image sensor after adhesively fixing the flexible substrate onto a bottom surface of the wafer.

16. The method of manufacturing the camera module package according to claim 13 further includes forming an IR filter layer on the top surface of the lens formed in the lens unit in a convex shape before dividing the camera module package into the individual camera module packages by dicing the camera module package.

17. The method of manufacturing the camera module package according to claim 13 further includes forming a metallic thin layer for preventing scattered light from penetrating on a top surface of the lens unit before dividing the camera module package into the individual camera module packages by dicing the camera module package.

18. The method of manufacturing the camera module package according to claim 13, the wafer is formed in a thickness of approximately 50 μm by thinning a surface opposite to the mounting surface of the image sensor and the pads in thinning the wafer.

19. The method of manufacturing the camera module package according to claim 13, wherein the via-hole is formed by dry etching such as a DRIE (Dry Reactive Ion Etching) method to form a resist layer by performing a photolithography process and open only a part of the resist layer to be etched in etching the via-hole to the wafer.

20. The method of manufacturing the camera module package according to claim 19, wherein a wall surface of the via-hole is formed at a right angle or of a taper surface.

21. The method of manufacturing the camera module package according to claim 13, wherein forming the conductive line by injecting conductive paste into the via-hole includes a paste injecting method for curing the paste through a reflow device after printing the conductive paste or solder paste on the wafer and a plating method for form a wire by copper-plating a seed layer after forming the seed layer to planarize the copper-plated surface through a Chemical Mechanical Planarization (CMP) process.

22. The method of manufacturing the camera module package according to claim 13, wherein the lens unit is formed by a laminating method using a liquid material and a film sheet which are made of a polymer material and a spin-coating method in forming the lens unit on the top surface of the wafer.

23. A method of manufacturing a camera module package comprising:
mounting an image sensor and pads on a top surface of a wafer with equal spacing;
thinning one surface of the wafer so as to form the wafer thin;
etching the wafer to form a via-hole on a surface opposite to a mounting surface of the pad;
forming a conductive line by injecting conductive paste into the via-hole formed in the wafer;
adhesively fixing a flexible substrate in which an internal circuit pattern is formed on a conductive line formation surface of the wafer;
adhering a film sheet made of a polymer onto an upper part of mounting surfaces of the image sensor and the pad of the wafer including a top surface of the image sensor by using a laminator apparatus;
forming the lens by forming patterns on the film sheet through a photolithography process, that is, an exposure or a development and softening the formation part of the patterns through a reflow process in a state that the pattern is formed; and
dividing the completed camera module package into individual camera module packages by dicing the completed package in a wafer level state.

24. A method of manufacturing a camera module package comprising:
mounting an image sensor and pads on a top surface of a wafer with equal spacing;
thinning one surface of the wafer so as to form the wafer thin;
etching the wafer to form a via-hole on a surface opposite to a mounting surface of the pad;
forming a conductive line by injecting conductive paste into the via-hole formed in the wafer;
adhesively fixing a flexible substrate in which an internal circuit pattern is formed on a conductive line formation surface of the wafer;
adhering a first film sheet made of a polymer material onto the top surface of the wafer including a top surface of an image sensor by using a laminator apparatus;
forming a top surface of the first film sheet thin through an exposure, a development, or a thinning process and laminating a second film sheet different from the first film sheet on the top surface of the first film sheet;
forming the lens as the second film sheet is formed in a pattern and the second film sheet is softened by a reflow process; and
dividing the completed camera module package into individual camera module packages by dicing the completed package in a wafer level state.

25. A method of manufacturing a camera module package comprising:
mounting an image sensor and pads on a top surface of a wafer with equal spacing;
thinning one surface of the wafer so as to form the wafer thin;
etching the wafer to form a via-hole on a surface opposite to a mounting surface of the pad;
forming a conductive line by injecting conductive paste into the via-hole formed in the wafer;
adhesively fixing a flexible substrate in which an internal circuit pattern is formed onto a conductive line formation surface of the wafer;
adhering a first film sheet made of a polymer material onto the top surface of the wafer including a top surface of an image sensor by using a laminator apparatus;
laminating a second film sheet different from the first film sheet by forming patterns on the top surface of the first film sheet with equal spacing;
forming the lens as the second film sheet is formed in the patterns and the second film sheet is softened by a reflow process; and
dividing the completed camera module package into individual camera module packages by dicing the completed package in a wafer level state.

26. A method of manufacturing a camera module package comprising:
mounting an image sensor and pads on a top surface of a wafer with equal spacing;
thinning one surface of the wafer so as to form the wafer thin;
etching the wafer to form a via-hole on a surface opposite to a mounting surface of the pad;
forming a conductive line by injecting conductive paste into the via-hole formed in the wafer;
adhesively fixing a flexible substrate in which an internal circuit pattern is formed on a conductive line formation surface of the wafer;
spin-coating the top surface of the wafer including a top surface of the image sensor with a liquid polymer;
forming the pattern by curing the wafer having the spin-coated layer formed on the top surface of the wafer and performing a lithography process on the cured spin-coated layer having a mask formed thereon;
laminating a second film sheet different from the first film sheet by forming patterns on the top surface of the first film sheet with equal spacing;
forming the lens as the patterns are softened by a reflow process in a state that the patterns using the mask are formed; and
dividing the completed camera module package into individual camera module packages by dicing the completed package in a wafer level state.

27. The camera module package according to claim 2, wherein the IR filter layer is formed on a top surface of the image sensor mounted on the top surface of the wafer.
